(19) United States
(12) Patent Application Publication
(10) Pub. No.: US 2006/0120493 A1
(43) Pub. Date: Jun. 8, 2006

(54) Maintaining a selected slice level

(76) Inventors: Yunteng Huang, Irvine, CA (US); Susumu Hara, Austin, TX (US); Gary Hammes, Topeka, KS (US)

Correspondence Address: TROP PRUNER & HU, PC, 8554 KATY FREEWAY, SUITE 100, HOUSTON, TX, 77024, US

(21) Appl. No.: 11/005,137

(22) Filed: Dec. 6, 2004

(51) Int. Cl. H03D 1/04

(52) U.S. Cl. 375/346

(57) ABSTRACT

In one embodiment, the present invention includes a method for removing a DC offset from a loop having an amplifier coupled to receive an input signal, applying a selected slice level to the loop, and measuring an offset slice level at an output of the amplifier based on the applied selected slice level. The offset slice level may be stored and used to maintain the selected slice level of the amplifier.

### FIELD OF THE INVENTION

The present invention relates to data communication and more particularly to acquiring data and clock signals associated with the data communication.

### BACKGROUND

Communication systems often transmit data with a clock embedded in a data stream, rather than being sent as a separate signal. When the data stream is received, a clock and data recovery circuit (CDR) recovers the embedded clock and retimes the received data to the recovered clock. Oftentimes, a CDR is implemented in an integrated circuit along with additional components, such as a limit amplifier (LA) and other such components. The LA may receive a voltage signal from a transimpedance amplifier (TIA) or other amplifier, which amplifies an incoming converted optical signal. Instead of a LA, an automatic gain control (AGC) amplifier may be used.

The function of the limit amplifier is to produce a consistent waveform from the TIA output which can be used by the CDR, regardless of incoming optical energy. In addition to amplifying the input signal, the LA may provide an adjustable slicing level to compensate for an asymmetric noise characteristic present in the incoming data. A slicing level is the threshold voltage at which an incoming signal is determined to be either a “1” bit or a “0” bit. At low levels of optical energy (corresponding to a zero bit level for example), the noise current is low. At higher levels of optical energy (corresponding to a one bit), the noise current may be higher. An optimal slice level for an amplifier in a receive path can enhance receiver performance significantly, especially in long-haul applications. Thus an offset is typically inserted into the receive path, either at an input of an amplifier or at an output thereof.

Optical signals are single-ended in nature. That is, a logic one value provides light, while a logic zero signal is dark. There is asymmetry in “1” and “0” signals when they are converted into the electrical domain, creating an asymmetrical data eye pattern. FIG. 1 is an eye diagram of a typical incoming data signal. As shown in FIG. 1, the waveform may correspond to incoming data, for example, being input into an electrical receiver. Data eye 5 is formed by superimposing waveforms of multiple data signals. In the real world, data signals forming a data eye have transitions with varied rise times and fall times and may also exhibit different voltage levels and shapes. As shown in FIG. 1, at a slicing level of 0 mV, the horizontal opening of the data eye 5 is smaller than the horizontal opening at a slicing level of −2 mV. Thus, a slicing level of zero may give a smaller amount of margin for the positive swing compared to the negative swing. In FIG. 1, the data eye 5 is shown to have its widest opening at a slicing level of −2 mV. If the slicing level is set to roughly −2 mV in the case shown, the margin is more symmetric and better results are possible. This asymmetry may require an introduction of an intentional offset to create the most reliable output. Thus, introducing a proper offset serves to optimize noise margin and hence achieve a lower bit error rate (BER).

A front end of a receiver (RXFE) has its own noise and offset due to circuit non-idealities. The lower frequency component of such noise may be termed as V_{OS} (offset voltage) when it is referred to the RXFE input. This V_{OS} adds to the incoming signal and it is the combined signal that is amplified by the amplifier. It is difficult for the amplifier and a corresponding CDR to discern the circuit offset voltage (i.e., V_{OS}) from a user-applied slice value. Furthermore, V_{OS} can vary significantly over time due to temperature and process variations, supply characteristics, and aging of the part. Thus power-on calibration is not a viable solution, and a need exists to adjust slice level during operation to improve performance.

As a result, some systems simply input a slice level at an input of a receiver amplifier, such as a LA. However, such slice level control only works well when the circuit offset from the amplifier is much smaller than the target receiver sensitivity and where the offset from the LA is non-varying. Such an implementation is impractical for a complementary metal oxide semiconductor (CMOS) implementation, due to large and varying LA offsets, especially in high data rate applications.

Another approach used is to replicate LA gain stages in a separate slice path to match gains present within the LA, and apply an offset to the LA through a feedback loop, such that the offset at the output of the LA matches the desired input slice level times the gain of the replica gain stages in the slice path. This scheme allows a somewhat accurate input-referred slice. However, such a system suffers from drawbacks including extra chip real estate used by the replica circuitry and imperfect matching, as well as the additional power consumed thereby.

Accordingly a need exists to provide an improved manner of offset cancellation and slice level adjustment.

### SUMMARY OF THE INVENTION

In certain embodiments, the present invention includes apparatus and methods to maintain a desired slice level for an amplifier in a receiver. In one such embodiment, the method includes removing a DC offset from a loop having an amplifier coupled to receive an input signal, applying a selected slice level to the loop, and measuring an offset slice level at the amplifier output based on the applied selected slice level. This measured level may then be used to maintain the desired slice level.

In another embodiment, a method to maintain a desired slice level may use a feedback loop coupled between an output and an input of an amplifier. In such a method, a DC offset from the amplifier output may be canceled. Furthermore, a selected slice level may be inserted into the feedback loop while it is opened, and a sensed offset of the amplifier while the feedback loop is opened may be captured. This captured value may then be used to maintain the desired slice level.

Embodiments of the present invention may be implemented in appropriate hardware, firmware, and software. To that end, one embodiment may be implemented in an integrated circuit having an amplifier and a feedback loop coupled to store a sensed offset of the amplifier for a selected slice level offset inserted into the amplifier. Still other embodiments may include a system including such an integrated circuit along with additional components, such as an additional amplifier used to convert incoming optical energy into voltage signals.

### BRIEF DESCRIPTION OF THE DRAWINGS

FIG. 1 is an eye diagram of a typical incoming data signal.

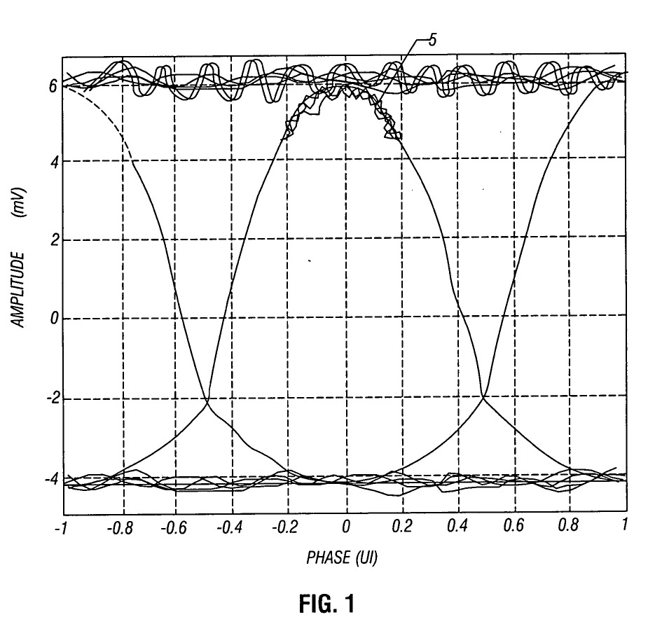

FIG. 2 is a flow diagram of a method in accordance with one embodiment of the present invention.

FIG. 3 is a block diagram of an exemplary embodiment of RXFE offset and slice level adjustment circuitry.

FIG. 4 is a timing diagram illustrating operation of the circuitry of FIG. 3.

FIG. 5 is a block diagram of an exemplary embodiment of proportional slicing circuitry.

FIG. 6 is a block diagram of a portion of a system in accordance with one embodiment of the present invention.

### DETAILED DESCRIPTION

In various embodiments, a loop may be provided in a receive signal path to provide a slice level control and offset cancellation for a receiver front end. In certain embodiments, a slice level offset may be manually provided based on a user-specified input value. Such a manual slice adjustment may occur in different manners, including an average value or duty cycle slicing mode, a proportional to peak slicing mode, and an absolute slicing mode.

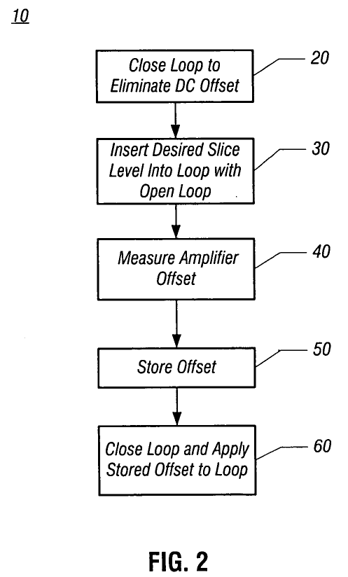

Referring now to FIG. 2, shown is a flow diagram of a method in accordance with one embodiment of the present invention. As shown in FIG. 2, method 10 may be performed within a receiver having a LA or other amplifier that has a feedback loop extending from its output to input. The feedback loop provides an offset value into the front end of the LA that is used to provide a desired slice level, as well as to cancel any RXFE offset.

As shown in FIG. 2, method 10 may begin by closing the feedback loop to eliminate the DC offset of the LA (block 20). As will be discussed further below, the loop includes various components, including sensing circuitry, converter circuitry, and accumulator circuitry. These circuitries may be used to remove any undesired DC component from the LA output, as well as to add in a desired slice offset set by a user. After the offset cancellation loops settles, the input referred offset of the RXFE may be stored in a digital register. This stored offset value is set such that the output of the LA contains zero DC component when this offset value is applied to the input of the RXFE.

Then, a desired slice level may be inserted into the loop (block 30) by adding it to the RXFE offset obtained earlier when the offset cancellation loop is closed. This slice level is applied while the loop is open, as will be discussed below. For example, for manual operation, a user-selected slice level, which may be a proportional or absolute slicing level, may be inserted into the loop. Next, the amplifier offset may be measured (block 40). Specifically, the output of the amplifier may be measured and the DC component thereof is the sensed offset of the amplifier output.

This sensed offset may then be stored (block 50). As an example, the offset may be digitized and stored for use within the feedback loop. In one embodiment, the digitized sensed offset may be stored in a register, and may be used to provide an appropriate offset level to the amplifier.

Finally, the loop is closed and the stored offset is applied to the loop (block 60). More specifically, the stored offset may be applied to accumulator circuitry to be added to or subtracted from the output of the LA. The resulting value may then be summed with the selected slice level adjustment, and the resulting sum is then provided to the input of the LA.

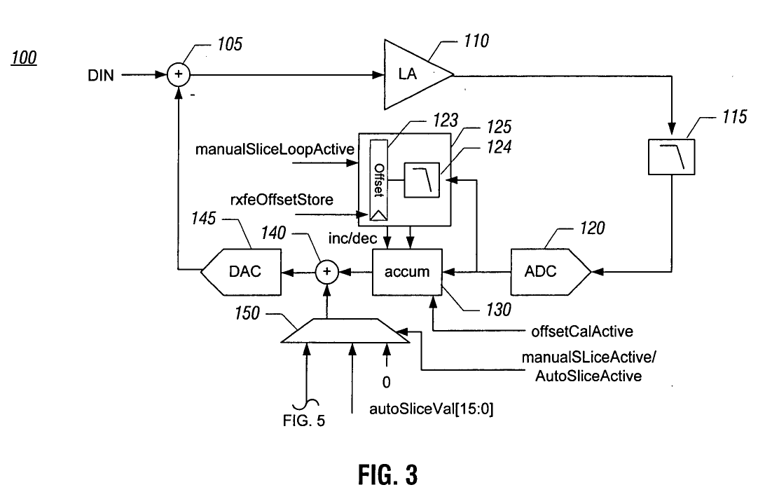

Referring now to FIG. 3, shown is a block diagram of an exemplary embodiment of RXFE offset and slice level adjustment circuitry. FIG. 3 shows a feedback loop 100 that may be incorporated into a receive path of optical signals, for example. In such an embodiment, loop 100 may be present within a CDR or other receiver of incoming signals. In one embodiment, loop 100 may be part of a single integrated circuit including a LA and a CDR, among other circuitry, although the scope of the present invention is not so limited.

As shown in FIG. 3, incoming data (DIN) is received at a summing block 105, where it is summed with an output of the feedback loop, as will be discussed further. The summed input is then provided to a LA 110 for amplification of the incoming signal. Feedback loop 100 begins at the output of LA 110, which is sensed by a low pass filter (LPF) 115, which acts as a sensing circuit. While not shown in FIG. 3, it is to be understood that the output of LA 110 is further coupled to additional receive circuitry, such as a CDR. The output of LPF 115 is provided to an analog-to-digital converter (ADC) 120 for digitization. The digitized output is coupled to a comparison circuitry 125, which includes a low pass filter 124 and a register 123 to store an offset value, and an accumulator 130. In one embodiment, accumulator 130 may be an integrator.

Loop 100 further includes a summing block 140, where the accumulator output is summed with the selected slice value, which may be a manually-selected value or an automatically-selected slice value provided via a multiplexer 150. The resulting summed signal is coupled to a digital-to-analog converter (DAC) 145 for conversion back to an analog signal, which is then provided as the RXFE offset and slice level to summing block 105, where it is summed with the incoming data signal, DIN.

In operation, loop 100 may progress through multiple states. Specifically, in one embodiment a RXFE offset cancellation state may first occur with loop 100 closed, to cancel the undesired DC offset present at the LA output while the desired slice offset is temporarily set to zero. Then a selected slice level may be applied to loop 100 while it is opened. As discussed, the selected slice level may be a manually or automatically selected slice level. After the circuit settles from the slice input, a sensed offset of the LA may be captured. This captured offset may then be stored. Finally, using the stored offset, loop 100 may again be closed, and normal operation may occur in which the sensed offset is maintained so that the desired slice level is provided to the LA.

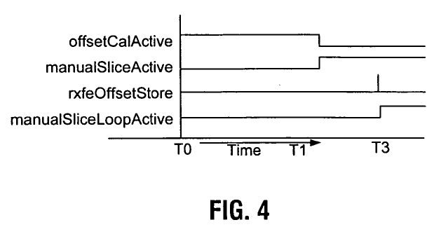

Referring now to FIG. 4, shown is a timing diagram illustrating operation of the circuit of FIG. 3 in one embodiment. As shown in FIG. 4, upon initiation of a part or upon a slice level change, for example, at time T0 an active high offset calibration control signal is present (offsetCalActive). When offsetCalActive is a logic high, RXFE offset loop 100 of FIG. 3 may act to cancel the RXFE offset. In this state, comparison circuitry 125 is disabled. Furthermore, in this state multiplexer 150 provides zero input into summing block 140. Accordingly, RXFE offset cancellation occurs and any DC offset of LA 110 is removed. While the time for offset cancellation varies, in certain embodiments, the offset calibration control signal may be active for between approximately 1 ms and 100 ms.

At the conclusion of offset cancellation at time T1, as shown in FIG. 4, offsetCalActive goes to a low state, and-a manual slice control signal (manualSliceActive) becomes a logic high. In this state, loop 100 is opened such that accumulator 130 is frozen. The selected slice level is input into loop 100, and the part is allowed to settle. In this state, the selected slice value is input via multiplexer 150 into summing block 140. Thus, the selected slice level is provided through DAC 145 to summing block 105, where it is summed with the incoming data signal. The resulting output signal is provided to LA 110 for amplification. In turn, the output of LA 110 is sensed in LPF 115 and converted to a digitized value in ADC 120. The digital output of ADC 120 is further low-pass filtered by LPF 124 to remove undesired noise. The filtered digital output is then stored in register 123. The time for the part to settle may be between approximately 1 ms and 100 ms, in certain embodiments. Upon settling, an offset store signal (rxfeOffsetStore) is activated, and the sensed offset is stored in offset register 123. Such storage of the sensed offset occurs at time T3 shown in FIG. 4. This sensed offset thus corresponds to the DC output of LA 110 caused by insertion of the selected slice level.

Thereafter, steady state operation of the part may begin with respect to maintaining the selected slice level. In such steady state operation, the selected slice level may be maintained by applying the stored sensed offset value from register 123 into accumulator 130. This operation may be enabled by activating a slice loop control signal (manualSliceLoopActive) into comparison circuitry 125.

Depending on its value, this sensed offset value increments or decrements the digitized output of ADC 120 to account for RXFE offset. Thus the output of ADC 120 is integrated in accumulator 130 with the stored offset. The resulting output of accumulator 130 is then combined with the selected slice level at summing block 140, which is converted back to an analog value via DAC 145 and provided to summing block 105, which is usually implemented as part of the LA. In such manner, a selected slice level value is maintained that fully accounts for DC offsets and other circuit non-idealities.

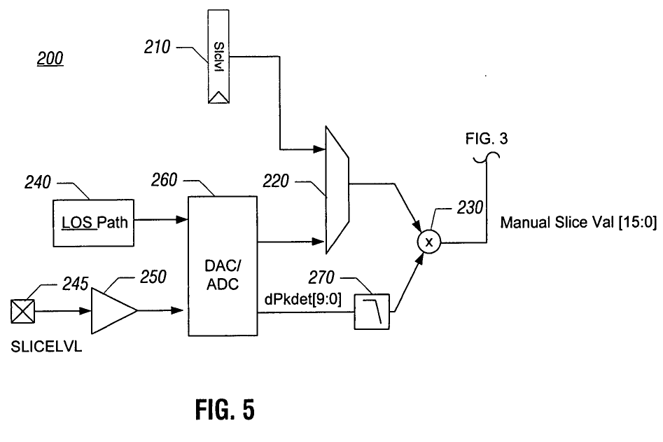

As discussed above, in some embodiments, a proportional mode of manual slice selection may be implemented. Referring now to FIG. 5, shown is a block diagram of an exemplary embodiment of proportional slicing circuitry. As shown in FIG. 5, circuit 200 may be used to provide a manual slice level value, which may be provided to multiplexer 150 of FIG. 3.

In operation, circuit 200 may provide either an absolute slicing level or a proportional slicing level to multiplexer 150, based on a desired operation mode for slice level selection.

If an absolute slice level is selected, the slice level stored in a register 210 may be selected through a multiplexer 220 and a multiplier 230 to provide the selected slice level for use in the feedback loop.

If instead proportional slicing is desired, a loss of signal (LOS) path 240 may provide an input into a combined ADC/DAC 260, which in one embodiment may be a successive approximation register (SAR) ADC/DAC. LOS path 240 may include a peak detector and may provide a value representative of the peak signal of the incoming data. This peak signal may be converted in ADC 260 into a digital peak detect signal (dpkdet [9:0]) and provided to a low pass filter (LPF) 270, which provides a filtered value to multiplier 230. LPF 270 filtering corner can range from a few Hertz to a few kiloHertz, in some embodiments.

In a proportional mode of operation, multiplier 230 multiplies the selected slice level by the peak of the incoming signal to provide a proportional level for the selected slice level. For example, a user may select a proportional slice level of 25%. If LOS path 240 determines a peak signal of 100 mV exists, the output of multiplier 230 may report a slice level voltage of 25 mV. As discussed above, the output of multiplier 230 may be provided to multiplexer 150 of FIG. 3.

As further shown in FIG. 5, in some embodiments, a pin 245 may be present on an integrated circuit and may be used to receive an analog slice level value. This analog value may be coupled through a buffer 250 to ADC 260, where it is converted to a digital value and provided to multiplexer 220. In turn, multiplexer 220 provides the manual slice value to multiplier 230.

In another embodiment, slicing may occur according to an average value or duty cycle slicing mode of operation. Feedback loop 100 of FIG. 3 may be programmed to perform such average value slicing. Specifically, the desired slice level may be stored in offset register 123. This selected slice level may then be compared to the sensed offset of LA 110, which is sensed by LPF 115, converted to a digital signal in ADC 120, and provided to comparison circuit 125 for comparison. A correction value may then be inserted into the loop via accumulator 130 based on the comparison. From there, the slice offset may pass through summing block 140 (as only input thereto) and be converted in DAC 145 to an analog value, which is then added into the incoming signal at summing block 105. Accordingly, no opening and closing of the loop occurs in such a mode of operation. Instead, the loop is always on and offset cancellation occurs naturally.

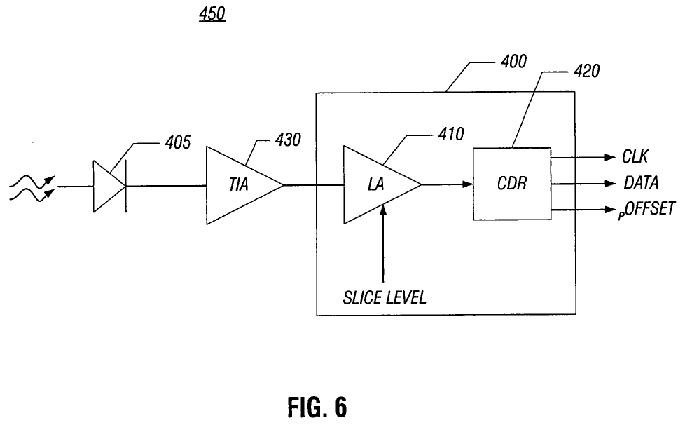

Referring now to FIG. 6, shown is a block diagram of a portion of a system in accordance with one embodiment of the present invention. System 450 may be a part of an optical system, such as an optical receiver. As shown in FIG. 6, system 450 receives incoming optical signals, which may be obtained from an optical fiber or other such source via a photodetecter 405, which converts the incoming optical energy into an electrical current. Then, a transimpedance amplifier (TIA) 430 may convert the electrical current into voltage signals. From the output of TIA 430, voltage signals are provided to an integrated circuit 400 as an incoming data stream. As shown in FIG. 6, integrated circuit 400 may include a LA 410 and a CDR 420. Specifically, the incoming data may be provided to LA 410 for amplification. As shown in FIG. 6, a slice level offset signal (SLICE LEVEL) may be provided to give a desired offset adjustment value to limit amplifier 410. For example, the slice level offset may be the output of DAC 145 of FIG. 3, for example, and may be referred to a front-end gain block of limit amplifier 410.

The output of LA 410 is provided to CDR 420. In turn, CDR 420 may generate outputs including recovered data (DATA) as well as a recovered clock signal (CLK), along with a phase offset signal (pOffset) which may report on the signal quality.

While shown with the particular components present in FIG. 6, it is to be understood that a system in accordance with an embodiment of the present invention may include additional components, and the components present in FIG. 6 may be differently arranged. For example, while integrated circuit 400 is shown to include a LA and a CDR, such components may be in different packages in other embodiments and, of course, additional components may be present in integrated circuit 400.

While various states of the feedback loop may be performed upon start up of a system including a CDR, in various embodiments such a process may be performed multiple times during system operation. For example, changes to a selected slicing level may occur over time, changes may occur due to different peak signals received by the receiver, or changes may occur due to temperature and process variations, vibrations on an optical fiber line, aging, and the like.

In some embodiments, the feedback loop may be controlled using software (or a combination of software, firmware and hardware) that may be executed within a system, such as a receiver, CDR, or other component. Such embodiments may include an article in the form of a machine-readable storage medium onto which there are stored instructions and data that form a software program to perform such methods of progressing through the different stages of the feedback loop, including the opening and closing of the loop to cancel a RXFE offset, apply a slice level and capture a sensed offset, and then to maintain the sensed offset.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
removing a DC offset from a loop having an amplifier coupled to receive an input signal;
applying a selected slice level to the loop; and
measuring an offset slice level at an output of the amplifier based on the applied selected slice level.

2. The method of claim 1, further comprising storing the measured offset slice level in a storage coupled to the loop.

3. The method of claim 1, further comprising summing the selected slice level and the measured offset slice level to obtain a loop offset value.

4. The method of claim 3, further comprising inserting the loop offset value into the input signal at an input of the amplifier.

5. The method of claim 1, wherein the selected slice level comprises a user-selected slice level.

6. The method of claim 5, wherein the user-selected slice level comprises a proportionate slice level.

7. The method of claim 1, further comprising closing the loop before removing the DC offset.

8. The method of claim 7, further comprising opening the loop before applying the selected slice level.

9. The method of claim 8, further comprising closing the loop before inserting a loop offset value into the loop.

10. A method comprising:
canceling a DC offset from an output of an amplifier in a receive path of an input signal;
inserting a selected slice level into a feedback loop coupled to the receive path while the feedback loop is opened; and
capturing a sensed offset of the amplifier while the feedback loop is opened.

11. The method of claim 10, further comprising storing the sensed offset.

12. The method of claim 11, further comprising closing the loop and applying the stored sensed offset to the feedback loop.

13. The method of claim 12, further comprising integrating the stored sensed offset with a feedback signal of the amplifier to obtain an integrated signal.

14. The method of claim 13, further comprising:
summing the selected slice level with the integrated signal to obtain a sum offset signal; and
inserting the sum offset signal into the receive path.

15. An integrated circuit comprising:
an amplifier; and
a feedback loop coupled to store a sensed offset of the amplifier for a selected slice level offset inserted into the amplifier.

16. The integrated circuit of claim 15, wherein the feedback loop to remove a DC offset of the amplifier.

17. The integrated circuit of claim 16, wherein the feedback loop comprises a low pass filter to sense the DC offset of the amplifier.

18. The integrated circuit of claim 17, further comprising an accumulator coupled to the low pass filter to remove the DC offset.

19. The integrated circuit of claim 18, further comprising:
a first summing node to combine an output of the accumulator with the selected slice level; and
a second summing node to combine an output of the first summing node with an incoming signal.

20. The integrated circuit of claim 15, further comprising a register to store the sensed offset.

21. The integrated circuit of claim 16, wherein the feedback loop to open at a first time and to close at a second time.

22. The integrated circuit of claim 21, wherein the first time occurs after the DC offset is removed and the second time occurs after the sensed offset is stored.

23. A system comprising:
a first amplifier to convert a current signal into a voltage signal;
a second amplifier coupled to the first amplifier to amplify the voltage signal; and
a feedback loop coupled between an output and an input of the second amplifier, the feedback loop to selectively close to remove an offset output of the second amplifier and open to sense an offset of the second amplifier upon insertion of a selected slice level into the feedback loop.

24. The system of claim 23, wherein the feedback loop to store the offset.

25. The system of claim 23, wherein the feedback loop comprises a low pass filter to sense the offset and an accumulator coupled to the low pass filter to remove the offset output of the second amplifier.

26. The system of claim 25, further comprising:
a first summing node to combine an output of the accumulator with the selected slice level; and
a second summing node to combine an output of the first summing node with the voltage signal.

27. The system of claim 23, wherein the feedback loop to selectively close in a steady state to maintain the selected slice level using the offset.
